(19) United States
(12) Patent Application Publication
(10) Pub. No.: US 2026/0046500 A1
(43) Pub. Date: Feb. 12, 2026

(54) IMAGING DEVICE

(71) Applicants: KYOCERA Corporation, Kyoto (JP); DENSO CORPORATION, Kariya-city (JP)

(72) Inventors: Yuta IWAI, Sagamihara-shi (JP); Hiroyuki ABE, Yokohama-shi (JP); Atsushi KADOTA, Yokohama-shi (JP); Takeshi KAZAMA, Kariya-city (JP); Tatsuhiko FUTAMURA, Kariya-city (JP); Takahito NAKAMURA, Kariya-city (JP)

(73) Assignees: KYOCERA Corporation, Kyoto (JP); DENSO CORPORATION, Kariya-city (JP)

(21) Appl. No.: 19/290,648

(22) Filed: Aug. 5, 2025

(30) Foreign Application Priority Data
Aug. 7, 2024 (JP) 2024-131007

(51) Int. Cl. H04N 23/52; H04N 23/54; H04N 23/57; H05K 7/20

(52) U.S. Cl. CPC H04N 23/52; H04N 23/54; H04N 23/57; H05K 7/20145; H05K 7/20409

(57) ABSTRACT

An imaging device includes an imaging optical system, an imaging element, a circuit board, a housing, and a fan. The imaging element is located on an optical axis of the imaging optical system. The circuit board processes an image signal outputted by the imaging element. The housing has at least a first surface and a second surface. The first surface is on a first direction side. The first direction is parallel to the optical axis of the imaging optical system and faces an object. The second surface is on a second direction side. The second direction is perpendicular to the first direction and faces vertically upward. The housing surrounds the circuit board. The housing holds the circuit board in a heat-transferable manner. The fan blows air on at least a portion of the first surface and at least a portion of the second surface.

### CROSS-REFERENCE TO RELATED APPLICATION

The present application claims priority to Japanese Patent Application No. 2024-131007 filed on Aug. 7, 2024, the entire contents of which are incorporated herein by reference.

### TECHNICAL FIELD

The present disclosure relates to an imaging device.

### BACKGROUND

Imaging devices are increasingly being installed in vehicles and other mobile bodies to gain an understanding of the surroundings. Heat dissipation is required for such imaging devices. Therefore, it has been proposed to exchange the air in an imaging device using a ventilation fan. For example, see Patent Literature (PTL) 1.

### CITATION LIST

### Patent Literature

PTL 1: JP 2017-046051 A

### SUMMARY

An imaging device according to a first aspect includes:
an imaging optical system;
an imaging element located on an optical axis of the imaging optical system;
a circuit board configured to process an image signal outputted by the imaging element;
a housing comprising at least a first surface on a first direction side and a second surface on a second direction side, the first direction being parallel to the optical axis of the imaging optical system and facing an object, the second direction being perpendicular to the first direction and facing vertically upward, the housing surrounding the circuit board and holding the circuit board in a heat-transferable manner; and
a fan configured to blow air on at least a portion of the first surface and at least a portion of the second surface.

### BRIEF DESCRIPTION OF THE DRAWINGS

In the accompanying drawings:

FIG. 1 is an external perspective view of an imaging device according to an embodiment;

FIG. 2 is a functional block diagram illustrating the schematic configuration of an imager in FIG. 1;

FIG. 3 is a partial cross-sectional view of the imaging device of FIG. 1, cut in a plane perpendicular to a third direction and near a fan;

FIG. 4 is a bottom view of the imaging device of FIG. 1 as viewed from the opposite direction from a second direction;

FIG. 5 is a partial cross-sectional view illustrating the imaging device of FIG. 1 mounted on a mobile body; and

FIG. 6 is a partial cross-sectional view illustrating an imaging device of a variation of FIG. 1 mounted on a mobile body.

### DETAILED DESCRIPTION

Embodiments of the present disclosure are described below with reference to the drawings. Constituent elements that are the same in the drawings below are labeled with the same reference signs.

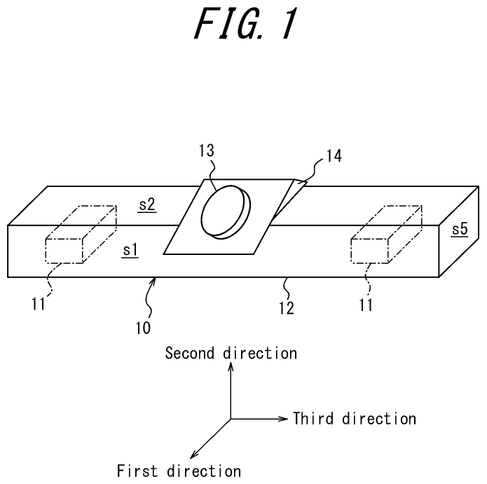

As illustrated in FIG. 1, an imaging device 10 according to one embodiment of the present disclosure is configured to include at least one imager 11, a housing 12, and a fan 13. The imaging device 10 may be configured to further include a fan cover 14. The imaging device 10 may be a stereo camera having two imagers 11.

The imaging device 10 may be designed to be mounted on a mobile body. The mobile body in the present disclosure may, for example, encompass not only vehicles but also aircraft. The vehicles may, for example, include automobiles, industrial vehicles, railway vehicles, vehicles for daily life, and fixed-wing aircraft that run on a runway. Automobiles may, for example, include passenger vehicles, trucks, buses, motorcycles, and trolley buses. Industrial vehicles may, for example, include industrial vehicles for agriculture and for construction. Industrial vehicles may, for example, include forklifts and golf carts. Industrial vehicles for agriculture may, for example, include tractors, cultivators, transplanters, binders, combines, and lawnmowers. Industrial vehicles for construction may, for example, include bulldozers, scrapers, backhoes, cranes, dump cars, and road rollers. Vehicles may include man-powered vehicles. The categories of vehicles are not limited to the above examples. For example, automobiles may include industrial vehicles that can be driven on the road. The same vehicle may also be included in multiple categories. Aircraft may, for example, include fixed-wing aircraft and rotorcraft.

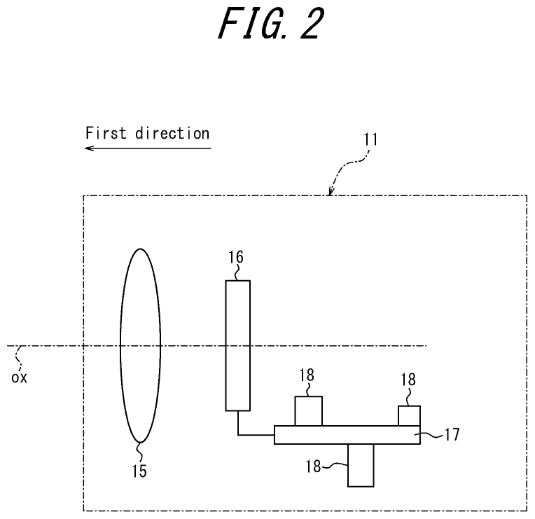

As illustrated in FIG. 2, the imager 11 may be configured to include an imaging optical system 15, an imaging element 16, and a circuit board 17.

The imaging optical system 15 may be configured to include at least one optical element such as a lens. The imaging optical system 15 may form an optical image of an object. The imaging optical system 15 has an optical axis, labeled “ox”. The direction that is parallel to the optical axis, ox, and toward the object is defined as a first direction in the present specification.

The imaging element 16 may be located on the optical axis, ox, of the imaging optical system 15. The imaging element 16 may be located at an image forming position of an optical image of an object that is separated from the imaging optical system 15 by a predetermined distance. The imaging element 16 captures an object image formed by the imaging optical system 15 and outputs an image signal corresponding to the object image. The imaging element 16 is, for example, a charge coupled device (CCD) or complementary metal oxide semiconductor (CMOS) image sensor.

The circuit board 17 processes the image signal outputted by the imaging element 16. The circuit board 17 may, for example, have electronic components 18 mounted thereon. The electronic components 18 are, for example, components for driving the imaging element 16 and for signal processing of the image signal.

In a configuration in which the imaging device 10 includes a plurality of imagers 11, such as a stereo camera, the circuit board 17 may be shared by the plurality of imagers 11. For example, the circuit board 17 in the imaging device 10 may extend from the position of any imager 11 to the position of any other imager 11.

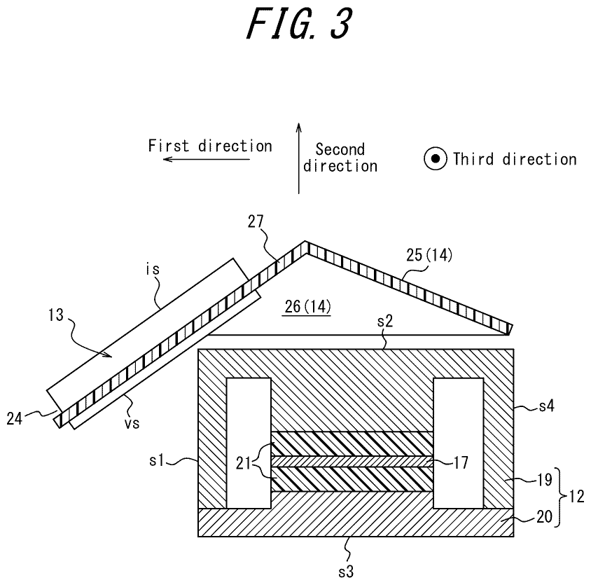

As illustrated in FIG. 3, the housing 12 surrounds the circuit board 17. The housing 12 may surround the entire surface of the circuit board 17. The housing 12 may house the circuit board 17. The housing 12 may be formed by a cover member 20 covering the opening of a box-shaped member 19 that is open on one side. The housing 12 may be formed of a material with high heat transfer characteristics, such as aluminum or another metal.

The housing 12 holds the circuit board 17 in a heat-transferable manner. Holding in a heat-transferable manner includes the housing 12 holding the circuit board 17 while in direct or indirect contact with the circuit board 17. Holding in a heat-transferable manner may also include holding the circuit board 17 while being in close proximity to but separated from the circuit board 17.

Indirect contact between the housing 12 and the circuit board 17 is, for example, a configuration in which a heat-dissipating member 21 is interposed and held between the circuit board 17 and the housing 12. Indirect contact between the housing 12 and the circuit board 17 may also, for example, be a configuration in which the electronic components 18 and the heat-dissipating member 21 are interposed and held between the circuit board 17 and the housing 12. The heat-dissipating member 21 is, for example, a highly flexible and heat-conductive silicone resin.

The housing 12 may be capable of transferring heat from the circuit board 17 from a plurality of directions. For example, the housing 12 may sandwich the circuit board 17, with the heat-dissipating member 21 therebetween, from the second direction and the opposite direction from the second direction. In such a configuration, the housing 12 is capable of transferring heat from the circuit board 17 via the heat-dissipating member 21 from the second direction and the opposite direction from the second direction.

The housing 12 has at least a first surface s1 and a second surface s2.

The first surface s1 is a surface on the first direction side in the housing 12. The surface on the first direction side may refer to a surface that is located on the first direction side from the center of the housing 12 and that faces the first direction. The surface that faces the first direction may include not only a surface whose normal is parallel to the first direction, but also a surface whose normal is in an angular range of, for example, ±45 degrees with respect to the first direction. A surface sandwiched between surfaces on the first direction side according to the above definition may be included in the first surface s1 even if it is outside the range of surfaces facing the first direction.

The second surface s2 is a surface on the second direction side in the housing 12. The second direction is perpendicular to the first direction. The second direction is also the direction in which the imaging device is designed to be mounted so that the second direction faces vertically upward in a mobile body resting on a horizontal plane. In other words, the second direction is the direction that faces vertically upward. The surface on the second direction side may refer to a surface that faces the second direction, similar to the surface on the first direction side. Vertically upward may mean that the vertical component is positive when the second direction is decomposed.

As illustrated in FIGS. 1 and 3, the housing 12 may further have a third surface s3, a fourth surface s4, a fifth surface s5, and a sixth surface. The third surface s3 is a surface on the opposite side from the second direction in the housing 12. The surface on the opposite side from the second direction may refer to a surface that faces the opposite direction from the second direction, similar to the surface on the first direction side. The fourth surface s4 is a surface on the opposite side from the first direction in the housing 12. The surface on the opposite side from the first direction may refer to a surface that faces the opposite direction from the first direction, similar to the surface on the first direction side. The fifth surface s5 is a surface on the third direction side in the housing 12. The third direction is perpendicular to both the first direction and the second direction. The surface on the third direction side may refer to a surface that faces the opposite direction from the third direction, similar to the surface on the first direction side. The sixth surface is a surface on the opposite side from the third direction in the housing 12. The surface on the opposite side from the third direction may refer to a surface that faces the opposite direction from the third direction, similar to the surface on the first direction side.

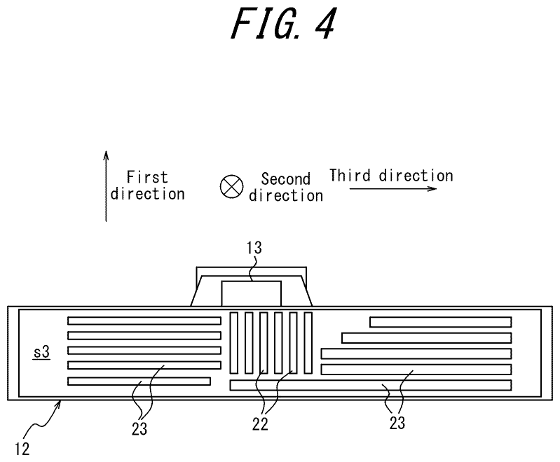

As illustrated in FIG. 4, the housing 12 may have a plurality of first fins 22, on the third surface s3, that have the first direction as the longitudinal direction. The first fins 22 may extend in a range of ±60° from the first direction. The first fins 22 may be provided in the third direction at any position in the region occupied by the fan 13 in the third direction. The housing 12 may have a plurality of second fins 23, on the third surface s3, that have the third direction as the longitudinal direction. The second fins 23 may be located outside of the region in which the first fins 22 are formed.

The housing 12 may also be provided with a plurality of fins on the first surface s1 and the second surface s2. For example, the housing 12 may be provided with fins extending in the first direction and fins extending in the third direction on the first surface s1 and the second surface s2, similar to the third surface s3.

As illustrated in FIG. 3, the fan 13 has a blowing surface labeled “vs”. In a configuration in which the fan 13 has a sleeve 24 for blowing air, the blowing surface, vs, is a virtual surface defined by an inner circle perpendicular to the axial direction at the air outlet of the sleeve 24. In a configuration in which the fan 13 is formed by a rotor blade and does not have the sleeve 24, the blowing surface, vs, may be any surface along the trajectory of the rotor blades in a rotating state, as viewed from the axial direction. The fan 13 may further have an intake surface labeled “is”.

The fan 13 is located so that the blowing surface, vs, faces at least a portion of the first surface s1 and at least a portion of the second surface s2. The fan 13 blows air onto the first surface s1 and the second surface s2. Specifically, the fan 13 is located near the boundary of the first surface s1 and the second surface s2 so as to be inclined in both the first direction and the second direction.

The fan cover 14 may direct, to the second surface s2, a component of the air blown by the fan 13, the component diffusing outside of the blowing surface, vs, as viewed from a blowing axis. In a configuration in which the fan 13 has the sleeve 24, the blowing axis is the central axis at the air outlet of the sleeve 24. In a configuration in which the fan 13 is formed by a rotor blade and does not have the sleeve 24, the blowing axis is the rotation axis. The fan cover 14 may, for example, include a second surface cover 25 and side covers 26.

The second surface cover 25 may be a plate material arranged so that the distance from the second surface s2 in the second direction becomes narrower towards the opposite direction from the first direction. The second surface cover 25 is more specifically a plate material extending from a holding plate 27, which holds the fan 13 and is perpendicular to the blowing axis, toward the end of the second surface s2 at the opposite side from the first direction.

The side covers 26 may be provided at positions at both ends along the third direction of the holding plate 27 and the second surface cover 25. The side covers 26 may be flat plate-like materials perpendicular to the third direction at these positions. Alternatively, the side covers 26 may be flat plate-like materials at both ends of the holding plate 27 along the third direction, inclined so that the angle between the side cover 26 and the holding plate 27 is between 90° and 170°. The side covers 26 may be substantially triangular in shape and may be connected to the sides, in the third direction, of the holding plate 27 and the second surface cover 25 farther in the second direction from the second surface s2.

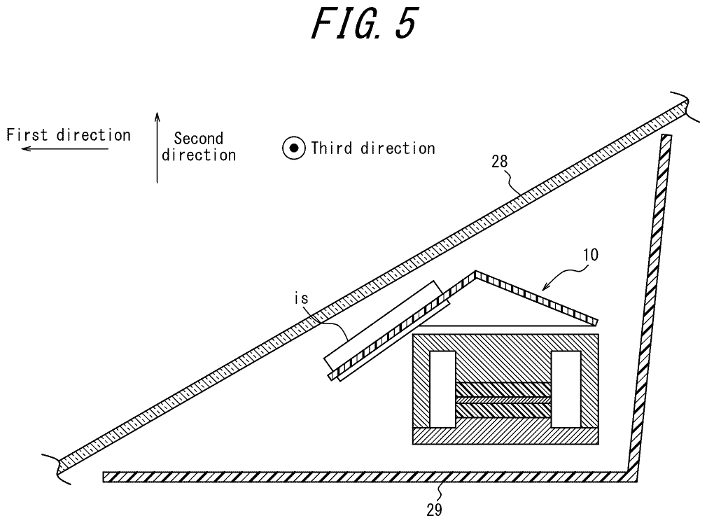

The imaging device 10 may be mounted on a mobile body that has a windshield. As illustrated in FIG. 5, the imaging device 10 may be mounted on the mobile body so that the intake surface, is, faces a windshield 28. In greater detail, the imaging device 10 may have a gap provided between the intake surface, is, and the windshield. The imaging device 10 may have a fixture for mounting onto the mobile body so that the intake surface, is, faces the windshield 28. The imaging device 10 may be covered on the opposite side from the second direction and the opposite side from the first direction by a cover material 29 when mounted on the mobile body.

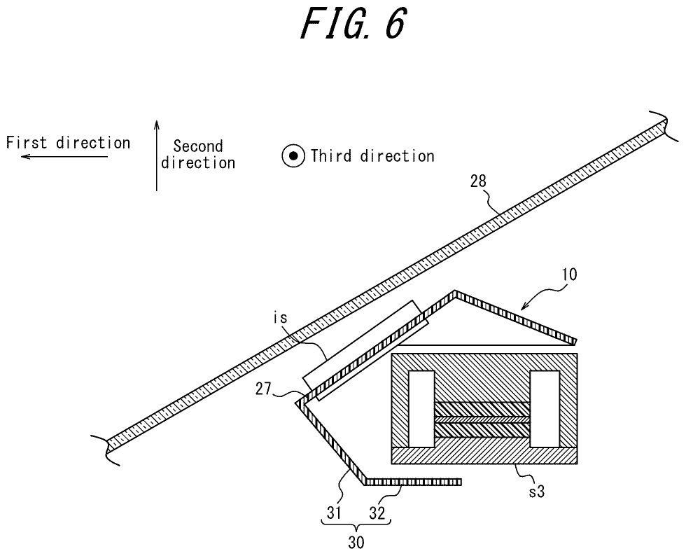

In a configuration in which the imaging device 10 is mounted on a mobile body without being covered by the cover material 29, the imaging device 10 may have a guide plate 30, as illustrated in FIG. 6. The guide plate 30 may direct the air blown from the fan 13 to the third surface s3. The guide plate 30 may specifically have a first portion 31 and a second portion 32. The first portion 31 and the second portion 32 may be plates parallel to the third direction. The first portion 31 may extend from the edge of the holding plate 27 on the first direction side toward the opposite sides from each of the first and second directions. The first portion 31 may terminate beyond the third surface s3 in the opposite direction from the second direction. The second portion 32 may extend from the edge of the first portion 31 on the opposite side from the second direction toward the opposite direction from the first direction.

The imaging device 10 in the present embodiment with the above-described configuration includes the imaging optical system 15, the imaging element 16 located on the optical axis, ox, of the imaging optical system 15, the circuit board 17 configured to process an image signal outputted by the imaging element 16, the housing 12 that includes at least the first surface s1 on the first direction side and the second surface s2 on the second direction side, the first direction being parallel to the optical axis, ox, of the imaging optical system 15 and facing an object, the second direction being perpendicular to the first direction, the housing 12 surrounding the circuit board 17 and holding the circuit board 17 in a heat-transferable manner, and the fan 13 located so that the blowing surface, vs, faces at least a portion of the first surface s1 and at least a portion of the second surface s2 and configured to blow air on the first surface s1 and the second surface s2. With this configuration, the imaging device 10 can cause the housing 12, to which the heat generated by the circuit board 17 is transferred, to dissipate heat in multiple directions. The imaging device 10 can therefore cause the circuit board 17 to dissipate heat in multiple directions, which improves heat dissipation compared to a configuration in which air is blown toward a single surface.

The imaging device 10 of the present embodiment may further include the fan cover 14 that directs, to the second surface s2, a component of the air blown by the fan 13, the component diffusing outside of the blowing surface, vs, as viewed from the blowing axis of the fan 13. With this configuration, the imaging device 10 can reduce the component, of the air blown by the fan 13, that does not contribute to heat dissipation of the housing 12. The imaging device 10 therefore further improves heat dissipation.

In the imaging device 10 of the present embodiment, the housing 12 has a plurality of fins on the third surface s3 on the opposite side from the second direction, the plurality of fins having the first direction as the longitudinal direction. As mentioned above, the imaging device 10 is generally covered on the opposite side from the second direction by the cover material 29 in a mobile body. By application to such a general configuration, or the addition of the guide plate 30, the imaging device 10 having the above-described configuration can cause the air, from the fan 13, that reaches the third surface s3 to travel in the opposite direction from the first direction along the third surface s3. The imaging device 10 therefore improves the heat dissipation at the third surface s3 of the housing 12, thereby further improving the heat dissipation overall.

The imaging device 10 of the present embodiment is mounted on a mobile object having the windshield 28 so that the intake surface, is, faces the windshield 28. With this configuration, the imaging device 10 can take air into the fan 13 through the intake surface, is, the air being from a defroster or the like in the mobile object and flowing along the windshield 28. The imaging device 10 can therefore use air delivered from a position away from the imaging device 10, thereby improving the cooling effect of the housing.

In an embodiment, (1) an imaging device includes
an imaging optical system;
an imaging element located on an optical axis of the imaging optical system;
a circuit board configured to process an image signal outputted by the imaging element;
a housing comprising at least a first surface on a first direction side and a second surface on a second direction side, the first direction being parallel to the optical axis of the imaging optical system and facing an object, the second direction being perpendicular to the first direction and facing vertically upward, the housing surrounding the circuit board and holding the circuit board in a heat-transferable manner; and
a fan configured to blow air on at least a portion of the first surface and at least a portion of the second surface.

(2) The imaging device according to (1) further includes a fan cover configured to direct, to the second surface, a component of the air blown by the fan, the component diffusing outside of a blowing surface of the fan as viewed from a blowing axis of the fan.

(3) In the imaging device according to (2), the housing includes a plurality of fins on a third surface on an opposite side from the second direction, the plurality of fins having the first direction as a longitudinal direction.

(4) In the imaging device according to any one of (1) to (3), the imaging device is attachable to a mobile body including a windshield so that an intake surface of the fan faces the windshield.

The drawings illustrating embodiments according to the present disclosure are merely schematic. The dimensional ratios and the like in the drawings do not necessarily match the actual dimensions.

Although embodiments of the present disclosure have been described through drawings and examples, it is to be noted that various changes and modifications may be made by those skilled in the art on the basis of the present disclosure. Therefore, such changes and modifications are to be understood as included within the scope of the present disclosure. For example, the functions and the like included in the various components may be reordered in any logically consistent way. Furthermore, components may be combined into one or divided.

Each of the features described in the present disclosure can be replaced by alternative features that function for the same, equivalent, or similar purposes, unless expressly denied. Therefore, unless expressly denied, each of the disclosed features is only one example of a comprehensive set of identical or equivalent features.

Furthermore, embodiments according to the present disclosure are not limited to any of the specific configurations of the embodiments described above. Embodiments according to the present disclosure can be extended to all of the novel features or combinations thereof described in the present disclosure.

The references to “first”, “second”, and the like in the present disclosure are identifiers for distinguishing between the corresponding elements. The numbers attached to elements distinguished by references to “first”, “second”, and the like in the present disclosure may be switched. For example, the identifiers “first” and “second” of the first surface and the second surface may be switched. Identifiers are switched simultaneously, and the elements are still distinguished between after identifiers are switched. The identifiers may be removed. Elements from which the identifiers are removed are distinguished by their reference sign. Identifiers in the present disclosure, such as “first” and “second”, may not be used in isolation as an interpretation of the order of elements or as the basis for the existence of an identifier with a lower number.

1. An imaging device comprising:
an imaging optical system;
an imaging element located on an optical axis of the imaging optical system;
a circuit board configured to process an image signal outputted by the imaging element;
a housing comprising at least a first surface on a first direction side and a second surface on a second direction side, the first direction being parallel to the optical axis of the imaging optical system and facing an object, the second direction being perpendicular to the first direction and facing vertically upward, the housing surrounding the circuit board and holding the circuit board in a heat-transferable manner; and
a fan configured to blow air on at least a portion of the first surface and at least a portion of the second surface.

2. The imaging device according to claim 1, further comprising a fan cover configured to direct, to the second surface, a component of the air blown by the fan, the component diffusing outside of a blowing surface of the fan as viewed from a blowing axis of the fan.

3. The imaging device according to claim 1, wherein the housing comprises a plurality of fins on a third surface on an opposite side from the second direction, the plurality of fins having the first direction as a longitudinal direction.

4. The imaging device according to claim 1, wherein the imaging device is attachable to a mobile body comprising a windshield so that an intake surface of the fan faces the windshield.
